(19) United States
(12) Patent Application Publication
(10) Pub. No.: US 2025/0044367 A1
(43) Pub. Date: Feb. 6, 2025

(54) BATTERY DATA MANAGEMENT APPARATUS AND OPERATING METHOD THEREOF

(71) Applicant: LG ENERGY SOLUTION, LTD., Seoul (KR)

(72) Inventors: Ju Young SUN, Daejeon (KR); Ho Seok KANG, Daejeon (KR); Deuk Joong KIM, Daejeon (KR)

(73) Assignee: LG ENERGY SOLUTION, LTD., Seoul (KR)

(21) Appl. No.: 18/717,106

(22) PCT Filed: Dec. 19, 2022
(86) PCT No.: PCT/KR2022/020750

§ 371 Date: Jun. 6, 2024

(30) Foreign Application Priority Data
Jan. 7, 2022 (KR) 10-2022-0003019

(51) Int. Cl. G01R 31/389; G01R 31/396

(52) U.S. Cl. CPC G01R 31/389; G01R 31/396

(57) ABSTRACT

A battery data management apparatus includes a controller for determining whether a battery is abnormal based on battery data, determining an abnormality level of the battery based on whether the battery is abnormal, and classifying and storing the battery data in a plurality of storages, based on the abnormality level of the battery; and a memory including the plurality of storages and a temporary storage temporarily storing the battery data.

### CROSS-REFERENCE TO RELATED APPLICATION

This application claims priority to and the benefit of Korean Patent Application No. 10-2022-0003019 filed in the Korean Intellectual Property Office on Jan. 7, 2022, the entire contents of which are incorporated herein by reference.

### TECHNICAL FIELD

Embodiments disclosed herein relate to a battery data management apparatus and an operating method thereof.

### BACKGROUND ART

An electric vehicle or an energy storage system (ESS) charges a plurality of batteries connected in series and/or in parallel and drives a motor with charged voltage to obtain power. The battery may have heat generated therein by chemical reaction occurring in a process of charging and discharging electricity, and the heat may impair performance and lifetime of the battery. Thus, a battery management system (BMS) may diagnose a state of the battery by monitoring battery data including temperature, voltage, and current of the battery.

A storage storing such large-volume battery data needs to efficiently manage accumulated battery data depending on importance and usage of the battery data. This is because the analysis of a cause for battery abnormality may occur depending on management method and type. Accordingly, there is a need for a battery data management apparatus and method capable of efficiently managing a storage that stores battery data.

### DISCLOSURE

### Technical Problem

Embodiments disclosed herein aim to provide a battery data management apparatus and an operating method thereof, in which battery data may be efficiently managed by separating a storage that stores the battery data.

Technical problems of the embodiments disclosed herein are not limited to the above-described technical problems, and other unmentioned technical problems would be clearly understood by one of ordinary skill in the art from the following description.

### Technical Solution

A battery data management apparatus according to an embodiment disclosed herein includes a controller configured to determine whether a battery is abnormal based on battery data, determine an abnormality level of the battery based on whether the battery is abnormal, and classify and store the battery data in a plurality of storages, based on the abnormality level of the battery and a memory including the plurality of storages and a temporary storage temporarily storing the battery data.

According to an embodiment, the controller may be further configured to store the battery data in any one of the plurality of storages, which corresponds to the abnormality level of the battery.

According to an embodiment, the controller may be further configured to, based on priorities of a plurality of storing regions of any one of the plurality of storages, store the battery data in any one of the plurality of storing regions.

According to an embodiment, the controller may be further configured to, when diagnosing that the battery is in an abnormal state, obtain battery data stored in the temporary storage at a time when the battery is diagnosed as being in the abnormal state, and battery data stored in the temporary storage after an elapse of a specific period, and classify and store the battery data in the plurality of storages.

According to an embodiment, the controller may be further configured to determine whether the battery corresponds to an abnormal level in descending order of risk level of the abnormality level.

According to an embodiment, the memory may store the battery data at regular intervals in a circular queue of the temporary storage.

According to an embodiment, the battery data may include at least any one of voltage, current, temperature, and diagnosis information of the battery.

An operating method of a battery data management apparatus according to an embodiment disclosed herein includes temporarily storing battery data, determining whether the battery is abnormal, based on the battery data, determining an abnormal level of the battery based on whether the battery is abnormal, and classifying and storing the battery data in a plurality of storages, based on the abnormal level of the battery.

According to an embodiment, the determining of the abnormal level of the battery based on whether the battery is abnormal may include storing the battery data in any one of the plurality of storages, which corresponds to the abnormality level of the battery.

According to an embodiment, the classifying and storing of the battery data in the plurality of storages, based on the abnormal level of the battery, may include, based on priorities of a plurality of storing regions of any one of the plurality of storages, storing the battery data in any one of the plurality of storing regions.

According to an embodiment, the temporarily storing of the battery data may include, when diagnosing that the battery is in an abnormal state, obtaining battery data stored in the temporary storage at a time when the battery is diagnosed as being in the abnormal state, and battery data stored in the temporary storage after an elapse of a specific period, and classifying and storing the battery data in the plurality of storages.

According to an embodiment, the determining of the abnormal level of the battery based on whether the battery is abnormal may include determining whether the battery corresponds to an abnormal level in descending order of risk level of the abnormality level.

According to an embodiment, the temporarily storing of the battery data may include storing the battery data at regular intervals in a circular queue of the temporary storage.

### Advantageous Effects

With a battery data management apparatus and an operating method thereof according to an embodiment disclosed herein, battery data may be efficiently managed by separating a storage that stores the battery data.

### DESCRIPTION OF DRAWINGS

FIG. 1 is a view schematically showing a configuration of a battery pack to which a battery data management apparatus according to an embodiment disclosed herein is applied.

FIG. 2 is a view showing a configuration of a battery data management apparatus according to an embodiment disclosed herein.

FIG. 3 is a view for describing in detail an overall operation of a battery data management apparatus according to an embodiment disclosed herein.

FIG. 4 is a view for describing in detail an overall operation of a battery data management apparatus according to another embodiment disclosed herein.

FIG. 5 is a flowchart of an operating method of a battery management apparatus according to an embodiment disclosed herein.

FIG. 6 is a block diagram showing a hardware configuration of a computing system for performing an operating method of a battery data management apparatus, according to an embodiment disclosed herein.

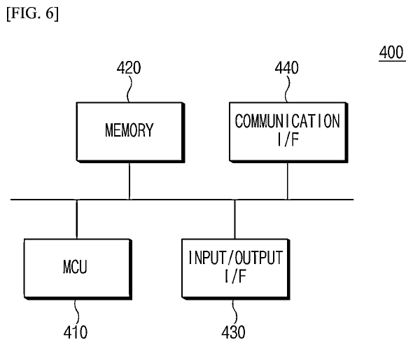

### MODE FOR INVENTION

Hereinafter, some embodiments disclosed in this document will be described in detail with reference to the exemplary drawings. In adding reference numerals to components of each drawing, it should be noted that the same components are given the same reference numerals even though they are indicated in different drawings. In addition, in describing the embodiments disclosed in this document, when it is determined that a detailed description of a related known configuration or function interferes with the understanding of an embodiment disclosed in this document, the detailed description thereof will be omitted.

To describe a component of an embodiment disclosed herein, terms such as first, second, A, B, (a), (b), etc., may be used. These terms are used merely for distinguishing one component from another component and do not limit the component to the essence, sequence, order, etc., of the component. The terms used herein, including technical and scientific terms, have the same meanings as terms that are generally understood by those skilled in the art, as long as the terms are not differently defined. Generally, the terms defined in a generally used dictionary should be interpreted as having the same meanings as the contextual meanings of the relevant technology and should not be interpreted as having ideal or exaggerated meanings unless they are clearly defined in the present document.

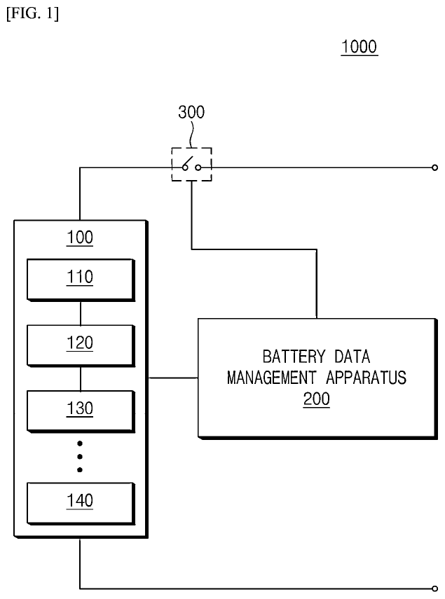

FIG. 1 illustrates a battery pack according to an embodiment disclosed herein.

Referring to FIG. 1, a battery pack 1000 according to an embodiment disclosed herein may include a battery module 100, a battery management apparatus 200, and a relay 300.

The battery module 100 may include a plurality of battery cells 110, 120, 130, and 140. Although the plurality of battery cells are illustrated as four in FIG. 1, the present disclosure is not limited thereto, and the battery module 100 may include n battery cells (n is a natural number equal to or greater than 2).

The battery module 100 may supply power to a target device (not shown). To this end, the battery module 100 may be electrically connected to the target device. Herein, the target device may include an electrical, electronic, or mechanical device that operates by receiving power from the battery pack 1000 including the plurality of battery cells 110, 120, 130, and 140, and the target device may be, for example, an electric vehicle (EV), but is not limited thereto.

The plurality of battery cells 110, 120, 130, and 140 may be a lithium ion (Li-ion) battery, an Li-ion polymer battery, a nickel-cadmium (Ni—Cd) battery, a nickel hydrogen (Ni-MH) battery, etc., and are not limited thereto. Meanwhile, although one battery module 100 is illustrated in FIG. 1, the battery module 100 may be configured in plural according to an embodiment.

The battery management apparatus 200 may manage and/or control a state and/or an operation of the battery module 100. For example, the battery management apparatus 200 may manage and/or control the states and/or operations of the plurality of battery cells 110, 120, 130, and 140 included in the battery module 100. The battery management apparatus 200 may manage charging and/or discharging of the battery module 100.

In addition, the battery management apparatus 200 may monitor a voltage, a current, a temperature, etc., of the battery module 100 and/or each of the plurality of battery cells 110, 120, 130, and 140 included in the battery module 100. A sensor or various measurement modules for monitoring performed by the battery management apparatus 200, which are not shown, may be additionally installed in the battery module 100, a charging/discharging path, any position of the battery module 100, etc. The battery management apparatus 200 may calculate a parameter indicating a state of the battery module 100, e.g., a state of charge (SoC), a state of health (SoH) etc., based on a measurement value, such as monitored voltage, current, temperature, etc. of each of the plurality of battery cells 110, 120, 130, and 140.

The battery management apparatus 200 may control an operation of the relay 300. For example, the battery management apparatus 200 may short-circuit the relay 300 to supply power to the target device. The battery management apparatus 200 may short-circuit the relay 300 when a charging device is connected to the battery pack 1000.

The battery management apparatus 200 may calculate a cell balancing time of each of the plurality of battery cells 110, 120, 130, and 140. Herein, the cell balancing time may be defined as a time required for balancing of the battery cell. For example, the battery management apparatus 200 may calculate a cell balancing time based on a SoC, a battery capacity, and a balancing efficiency of each of the plurality of battery cells 110, 120, 130, and 140.

The battery management apparatus 200 may include a power data management apparatus 210.

The battery data management apparatus 210 may obtain temperature and voltage measurement values of the plurality of batteries, and SoC and SoH parameters derived therefrom as data. The battery data management apparatus 210 may diagnose whether a battery is abnormal based on the obtained data. The battery data management apparatus 210 may classify and store battery data based on the obtained diagnosis result of whether the plurality of batteries are abnormal.

The battery data management apparatus 210 may transmit battery data obtained from the plurality of batteries to an external server to analyze and manage the battery data by using the external server having rich computing resources. Moreover, the battery data management apparatus 210 may precisely analyze an abnormal phenomenon of the battery through the external server to diagnose whether the battery is in an abnormal state in real time.

In addition, the battery data management apparatus 210 may analyze and manage the battery data obtained from the plurality of batteries by using internal components having rich computing resources. The battery data management apparatus 210 may also precisely analyze an abnormal phenomenon of the battery through the internal components to diagnose whether the plurality of batteries are in abnormal states.

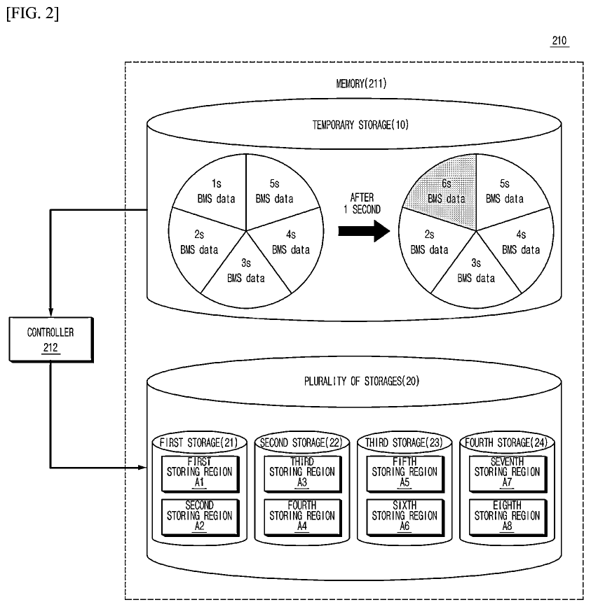

FIG. 2 is a block diagram showing a configuration of a battery data management apparatus according to an embodiment disclosed herein.

Hereinbelow, a configuration of the battery data management apparatus 210 will be described in detail with reference to FIG. 2.

First, referring to FIG. 2, the battery data management apparatus 210 may include a memory 211 and a controller 212.

The memory 211 may include a temporary storage 10 in which battery data of the battery data management apparatus obtained may be temporarily stored and a plurality of storages 20 in which the battery data may be classified and stored.

The temporary storage 10 may include a circular queue capable of storing the battery data at regular intervals. The queue may be defined as a data structure in which a continuous space is allocated such that first input data is output first. According to an embodiment, the circular queue may include 5 buffers. The buffer has a limited size of data that may be stored, and thus may temporarily store data continuously. The temporary storage 10 may temporarily store battery data continuously by using the circular queue including the 5 buffers.

The temporary storage 10 may temporarily store the battery data at regular time intervals. According to an embodiment, the temporary storage 10 may update the battery data every 1 second (every second) by using the circular queue including the 5 buffers. The controller 212 may analyze the battery data based on a regular time interval.

The controller 212 may analyze whether a battery is abnormal, based on the battery data stored in the temporary storage 10. More specifically, the controller 212 may analyze whether a battery is abnormal, based on voltage, current, and temperature data of the plurality of batteries. Herein, abnormality may be defined as a feature or a parameter of a component inside the system deviating from a prescribed condition by an allowable deviation or more.

For example, the controller 212 may diagnose that a battery is in an abnormal state when battery data including at least any one of voltage, current, temperature, and diagnosis information of a battery from time (t−5) to time t, stored in the temporary storage 10, deviates from previously stored conditions or preset conditions by an allowable deviation or more.

The controller 212 may further obtain and store battery data stored in the temporary storage 10 after elapse of a particular time when diagnosing that the battery is in the abnormal state, based on the battery data stored in the temporary storage 10. For example, when diagnosing that the battery is in the abnormal state based on the battery data from the time (t−5) to the time t, stored in the temporary storage 10, the controller 212 may further obtain battery data from time (t+1) to time (t+5), stored in the temporary storage 10, after an elapse of 5 seconds, thus storing battery data generated for a total of 10 seconds.

For example, the controller 212 may store battery data for 5 seconds up to an abnormality diagnosis occurrence time, and then further store battery data after an elapse of 5 seconds, thus storing a battery data history for 10 seconds before and after the abnormality diagnosis occurrence time. Thus, the controller 212 may identify a change in the battery data for 10 seconds before and after the abnormality diagnosis occurrence time.

The controller 212 may determine an abnormality level of the battery based on whether the battery is abnormal. For example, the controller 212 may determine whether abnormality occurs in the battery management apparatus 200, and determine an abnormality level of the occurring abnormality.

For example, the abnormality level may be determined according to severity, exposure, and controllability of damage caused by malfunction of vehicle parts through vehicle-level risk source analysis and risk assessment. For example, the abnormality level may be classified into four levels such as Fault2, Fault1, Warning, and Alarm. The abnormality level may define Fault2 as the highest risk level and Alarm as the lowest risk criterion. For example, when overvoltage or undervoltage occurs in a battery cell due to occurrence of a short-circuit in a battery module control cable of the BMS or a battery module diagnosis cable, such that a temperature of a battery rises and thus the risk of battery ignition is expected, then the abnormality level of the battery may be the Fault2 level.

The controller may classify and store the battery data in the plurality of storages 20, based on the abnormality level of the battery. For example, the plurality of storages 20 may include a first storage 21, a second storage 22, a third storage 23, and a fourth storage 24. The first storage 22, the second storage 23, the third storage 24, and the fourth storage 24 may be separated physically or programmatically (e.g., may be separate software). For example, the first storage 21 may store battery data corresponding to Fault2 that is the abnormality level of the battery. The second storage 22 may store battery data corresponding to Fault1 that is the abnormality level of the battery. The third storage 23 may store battery data corresponding to Warning that is the abnormality level of the battery. The fourth storage 24 may store battery data corresponding to Alarm that is the abnormality level of the battery.

Herein, each of the plurality of storages 20 may include a plurality of storing regions. Based on priorities of a plurality of storing regions of any one of the plurality of storages 20, the controller 212 may store battery data in any one of the plurality of storing regions. More specifically, the first storage 21 may include a first storing region A1 and a second storing region A2. The second storage 22 may include a third storing region A3 and a four storing region A4. The third storage 23 may include a fifth storing region A5 and a sixth storing region A6. The fourth storage 24 may include a seventh storing region A7 and an eighth storing region A8.

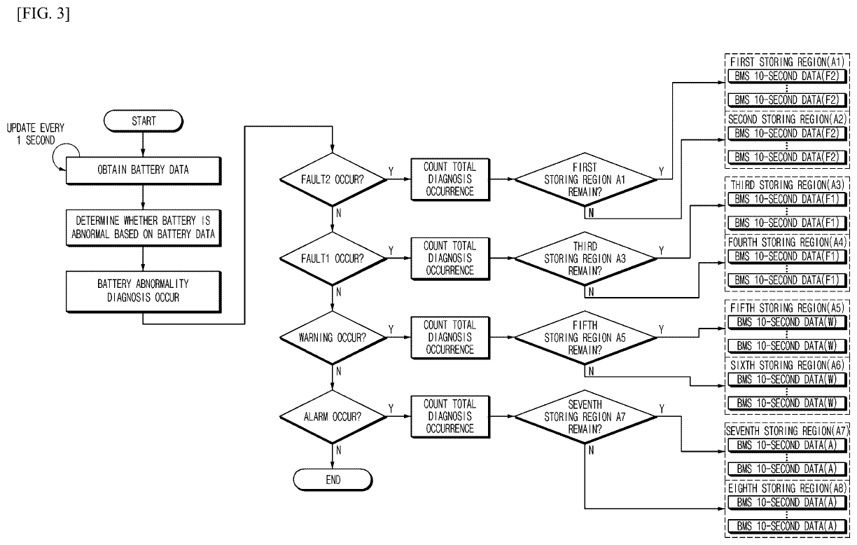

FIG. 3 is a view for describing in detail an overall operation of a battery data management apparatus according to an embodiment disclosed herein.

Referring to FIG. 3, the controller 212 may determine whether the battery corresponds to an abnormality level in descending order of risk level of the abnormality level. For example, the controller 212 may determine whether the battery corresponds to the abnormality level in order of whether the battery corresponds to the Fault 2 level, whether the battery corresponds to the Fault1 level, whether the battery corresponds to the Warning level, and then whether the battery corresponds to the Alarm level.

When determining the abnormality level of the battery, the controller 212 may classify and store battery data in any one of the plurality of storages, which corresponds to the abnormality level of the battery.

For example, when the abnormality level of the battery corresponds to Fault2, the controller 212 may determine whether a storage space exists in the first storing region A1 of the first storage 21. The controller 212 may store the battery data in the second storing region A2 when there is no storage space in the first storing region A1 of the first storage 21.

For example, when the abnormality level of the battery corresponds to Fault1, the controller 212 may determine whether a storage space exists in the third storing region A3 of the second storage 22. The controller 212 may store the battery data in the fourth storing region A4 when there is no storage space in the third storing region A3 of the second storage 22.

For example, when the abnormality level of the battery corresponds to Warning, the controller 212 may determine whether a storage space exists in the fifth storing region A5 of the third storage 23. The controller 212 may store the battery data in the sixth storing region A6 when there is no storage space in the fifth storing region A5 of the third storage 23.

For example, when the abnormality level of the battery corresponds to Alarm, the controller 212 may determine whether a storage space exists in the seventh storing region A7 of the fourth storage 24. The controller 212 may store the battery data in the eighth storing region A8 when there is no storage space in the seventh storing region A7 of the fourth storage 24.

Herein, the first storing region A1, the third storing region A3, the fifth storing region A5, and the seventh storing region A7 may be defined as battery data storage spaces for identifying an initial abnormality diagnosis occurrence history, and the second storing region A2, the fourth storing region A4, the sixth storing region A6, and the eighth storing region A8 may be defined as battery data storage spaces for identifying a recent abnormality diagnosis occurrence history.

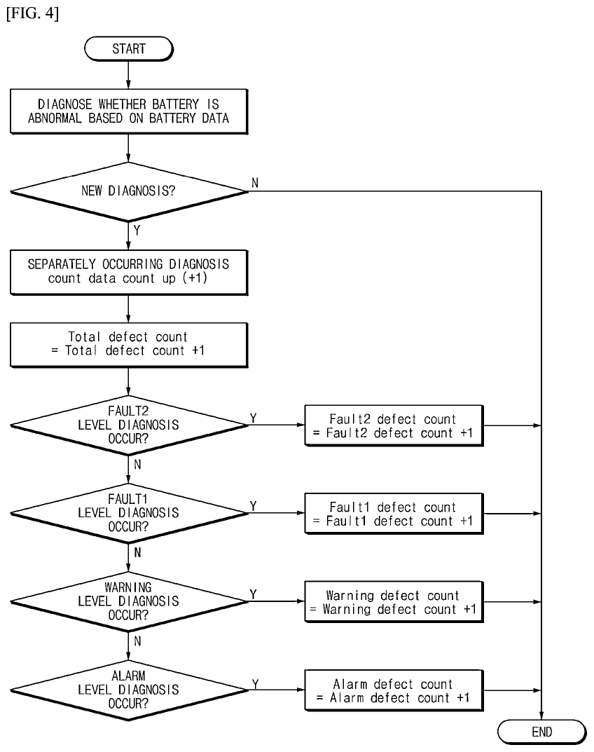

FIG. 4 is a view for describing in detail an overall operation of a battery data management apparatus according to another embodiment disclosed herein.

Referring to FIG. 4, the controller 212 may allocate count data to each abnormality level of the battery. When determining an abnormality level of the battery, the controller 212 may allocate count data to the corresponding abnormality level. That is, when determining the abnormality level of the battery, the controller 212 may increase count data corresponding to determination of the corresponding abnormality level.

The controller 212 may classify and store battery data in a plurality of storing regions of any one of the plurality of storages 20, based on the count data of the abnormality level, increased when determining the abnormality level of the battery.

For example, the controller 212 may store the battery data in the first storing region A1 when the abnormality level of the battery is Fault2 and a count value of the Fault2 level is within 10. The controller 212 may store the battery data in the second storing region A2 when the abnormality level of the battery is Fault2 and a count value of the Fault2 level exceeds 10.

For example, the controller 212 may store the battery data in the third storing region A3 when the abnormality level of the battery is Fault1 and a count value of the Fault1 level is within 10. The controller 212 may store the battery data in the fourth storing region A4 when the abnormality level of the battery is Fault1 and a count value of the Fault1 level exceeds 10.

For example, the controller 212 may store the battery data in the fifth storing region A5 when the abnormality level of the battery is Warning and a count value of the Warning level is within 10. The controller 212 may store the battery data in the sixth storing region A6 when the abnormality level of the battery is Warning and a count value of the Warning level exceeds 10.

For example, the controller 212 may store the battery data in the seventh storing region A7 when the abnormality level of the battery is Alarm and a count value of the Alarm level is within 10. The controller 212 may store the battery data in the eighth storing region A8 when the abnormality level of the battery is Alarm and a count value of the Alarm level exceeds 10.

Herein, a reference count value may be changed based on a size of a storing region, a size of a storage space, or a size of the memory 211.

As described above, with the battery data management apparatus 210 according to an embodiment disclosed herein, it is possible to efficiently manage battery data in several storages by separating a battery data storage.

The battery data management apparatus 210 may classify and manage battery data according to an abnormality level of a battery to separately manage battery data of high importance, thereby making it easy to track a cause for abnormality of the battery.

Moreover, it is possible to solve a problem that battery data of an abnormality level of no importance occupies a storing region of battery data corresponding to an abnormality of high importance due to frequency abnormality diagnosis when a storing region is separated for each abnormality level and a battery data storing region is not left.

The battery data management apparatus 210 may use a circular queue data structure including a plurality of buffers in a structure that stores only battery data obtained for 1 second when battery abnormality diagnosis occurs, thereby storing and analyzing battery data for several seconds before and after a battery abnormality diagnosis occurrence time and thus analyzing a change in battery data.

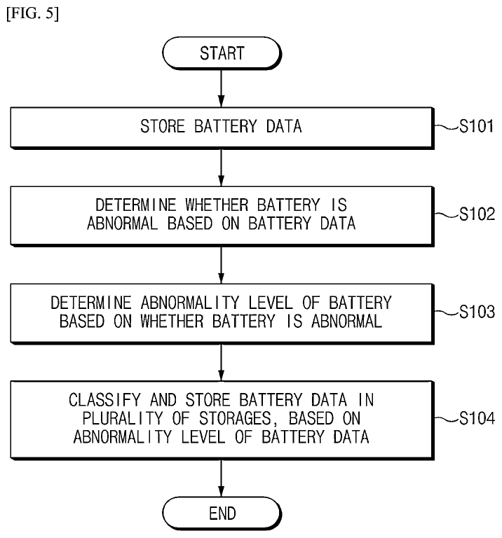

FIG. 5 is a flowchart of an operating method of a battery management apparatus according to an embodiment disclosed herein. Hereinbelow, an operating method of the battery data management apparatus 210 will be described with reference to FIGS. 1 to 4.

The battery data management apparatus 210 may be substantially the same as the battery data management apparatus 210 described with reference to FIGS. 1 to 4, and thus will be briefly described to avoid redundant description.

Referring to FIG. 5, the operating method of the battery data management apparatus may include operation S101 of storing battery data, operation S102 of determining whether a battery is abnormal based on the battery data, operation S103 of determining an abnormality level of the battery based on whether the battery is abnormal, and operation S104 of classifying and storing the battery data in a plurality of storages.

Hereinbelow, operations S101 through S104 will be described in detail.

In operation S101, the temporary storage 10 of the memory 211 may include a circular queue capable of storing the battery data at regular intervals. In operation S101, according to an embodiment, the circular queue may include 5 buffers. In operation S101, the temporary storage 10 of the memory 211 may temporarily store battery data by using the circular queue including the 5 buffers.

In operation S101, the temporary storage 10 of the memory 211 may temporarily store the battery data at regular time intervals. In operation S101, according to an embodiment, the temporary storage 10 of the memory 211 may update the battery data every 1 second (every second) by using the circular queue including the 5 buffers.

In operation S102, the controller 212 may analyze the battery data based on a regular time interval. In operation S102, the controller 212 may analyze whether the battery is abnormal, based on the battery data stored in the temporary storage 10 of the memory 211. In operation S102, more specifically, the controller 212 may analyze whether the battery is abnormal, based on voltage, current, and temperature data of the plurality of batteries.

In operation S102, for example, the controller 212 may diagnose that a battery is in an abnormal state when battery data including at least any one of voltage, current, temperature, and diagnosis information of a battery from time (t−5) to time t, stored in the temporary storage 10, deviates from previously stored conditions or preset conditions by an allowable deviation or more.

In operation S103, the controller 212 may further obtain and store battery data stored in the temporary storage 10 after an elapse of a particular time when diagnosing that the battery is in the abnormal state, based on the battery data stored in the temporary storage 10. In operation S103, for example, when diagnosing that the battery is in the abnormal state based on the battery data from the time (t−5) to the time t, stored in the temporary storage 10, the controller 212 may further obtain battery data from time (t+1) to time (t+5), stored in the temporary storage 10, after an elapse of 5 seconds, thus storing battery data generated for a total of 10 seconds.

In operation S103, for example, the controller 212 may store battery data for 5 seconds up to an abnormality diagnosis occurrence time, and then further store battery data after an elapse of 5 seconds, thus storing a battery data history for 10 seconds before and after the abnormality diagnosis occurrence time. Thus, the controller 212 may identify a change in the battery data for 10 seconds before and after the abnormality diagnosis occurrence time.

In operation S103, the controller 212 may determine an abnormality level of the battery when diagnosing that the battery is in the abnormal state based on the battery data. For example, the controller 212 may determine whether abnormality occurs in the battery management apparatus 200, and determine an abnormality level of the occurring abnormality.

In operation S103, the controller 212 may determine whether the battery corresponds to an abnormality level in descending order of risk level of the abnormality level. For example, the controller 212 may determine whether the battery corresponds to the abnormality level in order of whether the battery data corresponds to the Fault 2 level, whether the battery data corresponds to the Fault1 level, whether the battery data corresponds to the Warning level, and then whether the battery data corresponds to the Alarm level.

In operation S103, the controller 212 may allocate count data to each abnormality level of the battery. In operation S103, when determining an abnormality level of the battery, the controller 212 may allocate count data to the corresponding abnormality level. In operation S103, that is, when determining the abnormality level of the battery, the controller 212 may increase count data corresponding to determination of the corresponding abnormality level.

In operation S104, the controller 212 may monitor abnormality detection information including the abnormality level of the battery and classify and store the battery data according to the abnormality level. In operation S104, more specifically, the controller 212 may store the battery data in any one of the plurality of storages 20 corresponding to the abnormality level of the battery.

In operation S104, when diagnosing that the battery is in the abnormal state, the controller 212 may obtain battery data stored in a plurality of circular queues and battery data stored after an elapse of a specific period in the plurality of circular queues and classify and store the battery data in the plurality of storages 20.

Herein, each of the plurality of storages 20 may include a plurality of storing regions. In operation S104, based on priorities of a plurality of storing regions of any one of the plurality of storages 20, the controller 212 may store battery data in any one of the plurality of storing regions. More specifically, the first storage 21 may include a first storing region A1 and a second storing region A2. The second storage 22 may include a third storing region A3 and a four storing region A4. The third storage 23 may include a fifth storing region A5 and a sixth storing region A6. The fourth storage 24 may include a seventh storing region A7 and an eighth storing region A8.

In operation S104, for example, when the abnormality level of the battery corresponds to Fault2, the controller 212 may determine whether a storage space exists in the first storing region A1 of the first storage 21. The controller 212 may store the battery data in the second storing region A2 when there is no storage space in the first storing region A1 of the first storage 21.

FIG. 5 is a block diagram showing a hardware configuration of a computing system for performing an operating method of a battery data management apparatus, according to an embodiment disclosed herein.

Referring to FIG. 5, a computing system 400 according to an embodiment disclosed herein may include an MCU 410, a memory 420, an input/output I/F 430, and a communication I/F 440.

The MCU 410 may be a broker that executes various programs (e.g., a program for monitoring data of a battery, etc.) stored in the memory 420, processes various data through these programs, and performs the above-described functions of the battery data management apparatus 210 shown in FIG. 1.

The memory 420 may store various programs regarding operations of the computing system. Moreover, the memory 420 may store operation data of computing system.

The memory 420 may be provided in plural, depending on a need. The memory 420 may be volatile memory or non-volatile memory. For the memory 420 as the volatile memory, random access memory (RAM), dynamic RAM (DRAM), static RAM (SRAM), etc., may be used. For the memory 420 as the nonvolatile memory, read only memory (ROM), programmable ROM (PROM), electrically alterable ROM (EAROM), erasable PROM (EPROM), electrically erasable PROM (EEPROM), flash memory, etc., may be used. The above-listed examples of the memory 420 are merely examples and are not limited thereto.

The input/output I/F 430 may provide an interface for transmitting and receiving data by connecting an input device (not shown) such as a keyboard, a mouse, a touch panel, etc., and an output device such as a display (not shown), etc., to the MCU 410.

The communication I/F 440, which is a component capable of transmitting and receiving various data to and from a server, may be various devices capable of supporting wired or wireless communication. For example, a program for resistance measurement and abnormality diagnosis of the battery cell or various data may be transmitted and received to and from a separately provided external server through the communication I/F 440.

The above description is merely illustrative of the technical idea of the present disclosure, and various modifications and variations will be possible without departing from the essential characteristics of the present disclosure by those of ordinary skill in the art to which the present disclosure pertains.

Therefore, the embodiments disclosed in the present disclosure are intended for description rather than limitation of the technical spirit of the present disclosure and the scope of the technical spirit of the present disclosure is not limited by these embodiments. The protection scope of the present disclosure should be interpreted by the following claims, and all technical spirits within the same range should be understood to be included in the range of the present disclosure.

1. A battery data management apparatus comprising:
a controller configured to determine whether a battery is abnormal based on battery data, determine an abnormality level of the battery based on whether the battery is abnormal, and classify and store the battery data in a plurality of storages, based on the abnormality level of the battery; and
a memory comprising the plurality of storages and a temporary storage configured to temporarily store the battery data.

2. The battery data management apparatus of claim 1, wherein the controller is further configured to store the battery data in any one of the plurality of storages, which corresponds to the abnormality level of the battery.

3. The battery data management apparatus of claim 1, wherein the controller is further configured to, based on priorities of a plurality of storing regions of any one of the plurality of storages, store the battery data in any one of the plurality of storing regions.

4. The battery data management apparatus of claim 1, wherein the controller is further configured to, when diagnosing that the battery is in an abnormal state, obtain battery data stored in the temporary storage at a time when the battery is diagnosed as being in the abnormal state, obtain battery data stored in the temporary storage after a specific period, and classify and store the battery data in the plurality of storages.

5. The battery data management apparatus of claim 1, wherein the controller is further configured to determine whether the battery corresponds to an abnormal level in descending order of a risk level of the abnormality level.

6. The battery data management apparatus of claim 1, wherein the memory stores the battery data at regular intervals in a circular queue of the temporary storage.

7. The battery data management apparatus of claim 1, wherein the battery data comprises at least any one of voltage, current, temperature, and diagnosis information of the battery.

8. An operating method of a battery data management apparatus, the operating method comprising:
temporarily storing battery data;
determining whether the battery is abnormal, based on the battery data;
determining an abnormal level of the battery based on whether the battery is abnormal; and
classifying and storing the battery data in a plurality of storages, based on the abnormal level of the battery.

9. The operating method of claim 8, wherein the determining of the abnormal level of the battery based on whether the battery is abnormal comprises storing the battery data in any one of the plurality of storages, which corresponds to the abnormality level of the battery.

10. The operating method of claim 8, wherein the classifying and storing of the battery data in the plurality of storages, based on the abnormal level of the battery, comprises, based on priorities of a plurality of storing regions of any one of the plurality of storages, storing the battery data in any one of the plurality of storing regions.

11. The operating method of claim 8, wherein the temporarily storing of the battery data comprises, when diagnosing that the battery is in an abnormal state, obtaining battery data stored in a temporary storage at a time when the battery is diagnosed as being in the abnormal state, obtaining battery data stored in the temporary storage after a specific period, and classifying and storing the battery data in the plurality of storages.

12. The operating method of claim 8, wherein the determining of the abnormal level of the battery based on whether the battery is abnormal comprises determining whether the battery corresponds to an abnormal level in descending order of a risk level of the abnormality level.

13. The operating method of claim 8, wherein the temporarily storing of the battery data comprises storing the battery data at regular intervals in a circular queue of a temporary storage.

14. The battery data management apparatus of claim 1, wherein the controller is further configured to control at least one of states or operations of the battery based on the abnormality level.

15. The operating method of claim 8, further comprising:
controlling at least one of states or operations of the battery based on the abnormality level.
